(19) United States
(12) Patent Application Publication
(10) Pub. No.: US 2014/0179110 A1
(43) Pub. Date: Jun. 26, 2014

(54) METHODS AND APPARATUS FOR PROCESSING GERMANIUM CONTAINING MATERIAL, A III-V COMPOUND CONTAINING MATERIAL, OR A II-VI COMPOUND CONTAINING MATERIAL DISPOSED ON A SUBSTRATE USING A HOT WIRE SOURCE

(71) Applicant: APPLIED MATERIALS, INC., Santa Clara, CA (US)

(72) Inventors: JEONGWON PARK, Palo Alto, CA (US); JOE GRIFFITH CRUZ, San Jose, CA (US); PRAVIN K. NARWANKAR, Sunnyvale, CA (US)

(73) Assignee: APPLIED MATERIALS, INC., Santa Clara, CA (US)

(21) Appl. No.: 14/107,816

(22) Filed: Dec. 16, 2013

Related U.S. Application Data
(60) Provisional application No. 61/740,572, filed on Dec. 21, 2012.
(60) Provisional application No. 61/774,672, filed on Mar. 8, 2013.

(51) Int. Cl. H01L 21/3065

(52) U.S. Cl. CPC H01L 21/3065
USPC 438/715

(57) ABSTRACT

Methods and apparatus for processing a germanium containing material, a III-V compound containing material, or a II-VI compound containing material disposed on a substrate using a hot wire source are provided herein. In some embodiments, a method for processing a material disposed on a substrate, wherein the material is at least one of a germanium containing material, a III-V compound containing material, or a II-VI compound containing material, includes providing a hydrogen containing gas to a first process chamber having a plurality of filaments; flowing a current through the plurality of filaments to raise a temperature of the plurality of filaments to a first temperature sufficient to decompose at least a portion of the hydrogen containing gas to form hydrogen atoms; and treating a surface of an exposed material on a substrate by exposing the material to hydrogen atoms formed by the decomposition of the hydrogen containing gas.

### CROSS-REFERENCE TO RELATED APPLICATIONS

This application claims benefit of U.S. provisional patent application Ser. No. 61/740,572, filed Dec. 21, 2012, and U.S. provisional patent application Ser. No. 61/774,672, filed Mar. 8, 2013, each of which are herein incorporated by reference.

### FIELD

Embodiments of the present invention generally relate to semiconductor substrate processing, and more particularly, to methods for cleaning a substrate surface.

### BACKGROUND

Semiconductor device fabrication requires multiple process steps to complete a finished device. However, process steps or intervening conditions may produce unwanted materials (e.g., native oxide layers, contaminants, residues, or the like) that may deposit or form on structures of the device. Such materials are typically removed via substrate cleaning processes. Conventional substrate treating/cleaning processes typically include exposing the substrate to a plasma formed from a process gas (e.g. a fluorine containing gas) under high temperate and/or pressure. However, the inventors have observed that such methods may result in unacceptable damage to the substrate.

Therefore, the inventors have provided improved methods of cleaning device surfaces.

### SUMMARY

Methods and apparatus for processing a germanium containing material, a III-V compound containing material, or a II-VI compound containing material disposed on a substrate using a hot wire source are provided herein. In some embodiments, a method for processing a material on a substrate, wherein the material is at least one of a germanium containing material, a III-V compound containing material, or a II-VI compound containing material, includes providing a hydrogen containing gas to a first process chamber having a plurality of filaments; flowing a current through the plurality of filaments to raise a temperature of the plurality of filaments to a first temperature sufficient to decompose at least a portion of the hydrogen containing gas to form hydrogen atoms; and treating a surface of an exposed material on a substrate by exposing the material to hydrogen atoms formed by the decomposition of the hydrogen containing gas.

In some embodiments wherein the material is a germanium containing material, the method may further include providing a nitrogen containing gas to a second process chamber having a plurality of filaments; flowing a current through the plurality of filaments to raise a temperature of the plurality of filaments to a first temperature sufficient to decompose at least a portion of the nitrogen containing gas to form nitrogen atoms; and forming a nitrogen containing layer atop the germanium containing material by exposing the substrate to nitrogen atoms formed by the decomposition of the nitrogen containing gas.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram of a method for processing a substrate in accordance with some embodiments of the present invention.

FIGS. 2A-D are illustrative cross-sectional views of a substrate during different stages of the method of FIG. 1 in accordance with some embodiments of the present invention.

FIG. 3 is a processing system suitable for performing the method depicted in FIG. 1 in accordance with some embodiments of the present invention.

FIG. 4 is a processing system suitable for performing the method depicted in FIG. 1 in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods and apparatus for processing germanium containing materials, III-V compound containing materials, or II-VI compound containing materials disposed on substrates are provided herein. Embodiments of the inventive process may advantageously allow for removal of contaminants or undesired layers from substrates while causing less damage to the substrate as compared to conventional treating processes utilizing, for example, one or more of a plasma, a high temperature treatment or a fluorine based chemistry. Embodiments of the inventive process may further advantageously allow for the formation of nitrogen containing layers atop germanium containing material that display a conformal growth with smooth surfaces and sharp interfaces, as compared to nitrogen containing layers formed via conventional nitridation processes, for example such as a plasma nitridation process. Moreover, by utilizing a process chamber that utilizes a hot wire source to produce atomic hydrogen and/or atomic nitrogen, the inventors have observed that the hot wire processing chamber may advantageously produce a higher density population of atomic hydrogen and/or atomic nitrogen (e.g., such as 1.3 to about 3 times higher) as compared to methods conventionally used in the semiconductor industry to produce atomic hydrogen and/or atomic nitrogen.

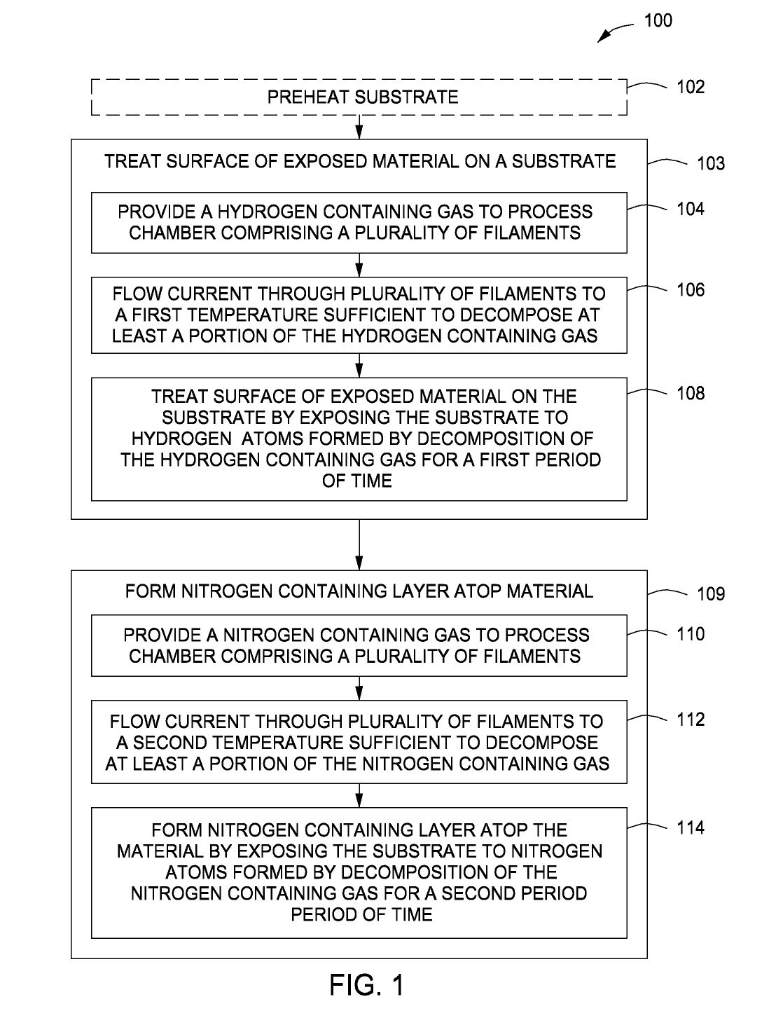

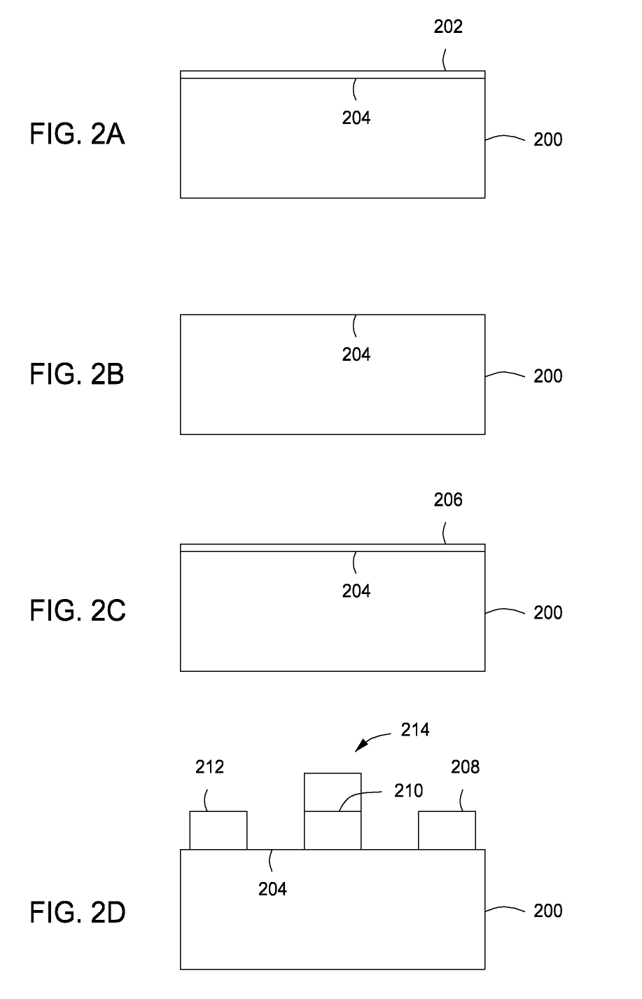

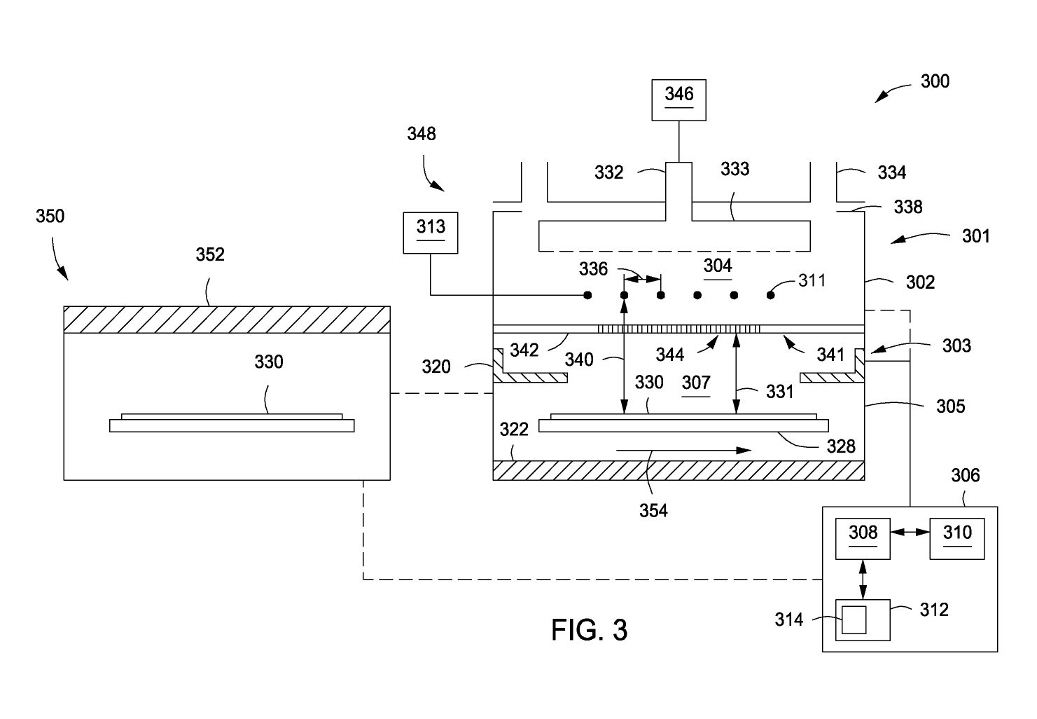

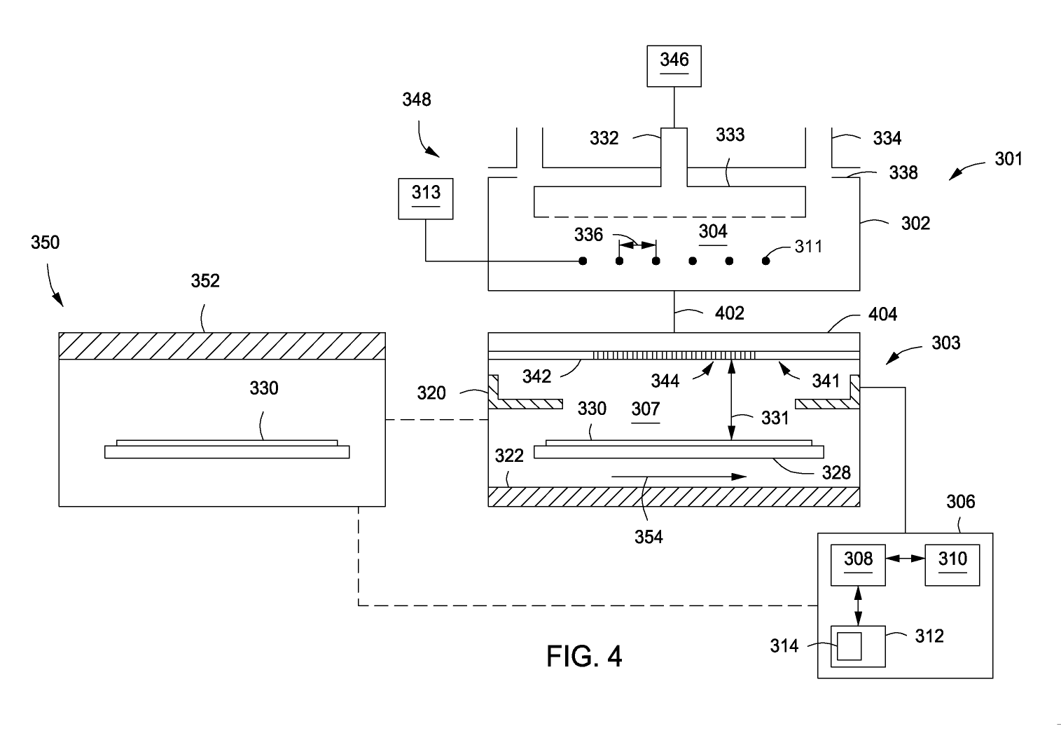

FIG. 1 is a flow diagram of a method 100 for processing a germanium material or a III-V or II-VI compound containing material on a substrate in accordance with some embodiments of the present invention. FIGS. 2A-D are illustrative cross-sectional views of the device having high aspect ratio structures during different stages of the processing sequence of FIG. 1 in accordance with some embodiments of the present invention. The inventive methods may be performed in any apparatus suitable for processing semiconductor substrates in accordance with embodiments of the present invention, such as the apparatus discussed below with respect to FIGS. 3 and 4.

The method 100 generally begins at 102 where a substrate having an exposed germanium containing material or III-V or II-VI compound containing material (substrate 200) may be optionally preheated. Preheating the substrate 200 prior to performing a treating process (e.g. the treating process as described below) may facilitate a de-gassing and/or removal of contaminants from the device. In some embodiments, the substrate 200 may be preheated in the same chamber as used for the treating process. Alternatively, in some embodiments, a preheat chamber different than that used for the treating process may be utilized (such as preheat chamber 350 discussed below with respect to FIGS. 3 and 4). The inventors have observed that preheating the substrate 200 in a different chamber than that used to perform the treating process may reduce or eliminate the incidence of contamination of the substrate with residual process byproducts from the treating process chamber and/or may reduce or eliminate the incidence of contamination of the treating process chamber with materials from the substrate.

The preheat chamber may be any type of chamber suitable to preheat the substrate 200 to a desired temperature, for example such as a dedicated preheat chamber, an annealing chamber, a deposition chamber, or the like. In some embodiments the preheat chamber may be a hot wire processing chamber (e.g., a hot wire chemical vapor deposition (HWCVD) chamber, or other suitable processing chamber having a hot wire source) such as the process chamber described below with respect to FIGS. 3 and 4. In some embodiments, the preheat chamber may be one of a plurality of chambers coupled to a multi-chamber tool, for example such as a cluster tool or an in-line process tool.

The substrate 200 may be preheated to any temperature suitable to de-gas or remove contaminants from the substrate 200. For example, in some embodiments, the substrate 200 may be preheated to a temperature of up to about 500 degrees Celsius. The substrate 200 may be preheated via any suitable heat source, for example, heating lamps or resistive heaters disposed within the chamber, heaters embedded within a substrate support, filaments of a hot wire source, or the like. In embodiments where the substrate 200 is preheated in a hot wire processing chamber, the hot wire source (e.g., the filaments) may be heated to a temperature of about 1000 to about 2500 degrees to facilitate preheating the substrate 200 to the desired temperature. Other temperatures may be used as appropriate for the substrate and the contaminants to be removed.

Referring to FIG. 2A, the substrate 200 may be any type of substrate having an exposed material and that is suitable for semiconductor device fabrication, for example, such as a doped or un-doped silicon substrate, a III-V compound substrate, a II-VI compound substrate, a silicon germanium (SiGe) substrate, an epi-substrate, a silicon-on-insulator (SOI) substrate, oxides thereof, or the like. In some embodiments, the substrate 200 may comprise a semiconductor device, for example such as a two dimensional or three dimensional device, such as a multigate device, fin field effect transistor (FinFET), metal oxide semiconductor field effect transistor (MOSFET), nanowire field effect transistor (NWFET), tri-gate transistor, or the like. In embodiments where the substrate 200 comprises a III-V compound, the substrate 200 may comprise any III-V compound suitable for semiconductor or LED device fabrication, for example, such as indium gallium arsenide (InGaAs), indium gallium phosphide (InGaP), gallium nitride (GaN), indium arsenide (InAs), indium phosphide (InP), gallium arsenide (GaAs), gallium phosphide (GaP), gallium indium arsenide antimonide phosphide (GaInAsSbP), or the like. In embodiments where the substrate 200 comprises a II-VI compound, the substrate 200 may comprise any II-VI compound suitable for semiconductor or LED device fabrication, for example such as cadmium sulfide (CdS), cadmium telluride (CdTe), zinc oxide (ZnO), zinc selenide (ZnSe), zinc sulfide (ZnS), zinc telluride (ZnTe), cadmium zinc telluride (CdZnTe), mercury cadmium telluride (HgCdTe), or the like. In some embodiments, the inventive method described with respect to 103-108 may be performed to remove unwanted materials (e.g., native oxide layers, contaminants, residues, or the like) that may deposit or form on the surface of process chamber components, including but not limited to chamber walls, a substrate support, or a showerhead.

In some embodiments, a layer 202 to be removed may be disposed atop one or more exposed germanium surfaces or III-V or II-VI compound containing material surfaces (e.g., surface 204) of the substrate 200. Although described herein as a layer, the layer 202 to be removed may also be a partial layer, or may be islands of material disposed only upon portions of the substrate 200. The layer 202 may comprise any materials that are to be removed from the substrate 200, for example, native oxide layers, nitride layers, dielectric layers, silicon layers or the like, or prior process residues or contaminants, for example, such as carbon, silicon, nitrogen or oxygen containing contaminants, or the like. In some embodiments, the layer 202 may be at least a portion of the surface 204 of the substrate 200 having a plurality of vertical deviations of the surface 204 of the substrate 200 that result in the surface 204 having an undesired roughness. The surface 204 may be any germanium containing surface, or III-V or II-VI compound containing surface that requires cleaning prior to and/or subsequent to a process (e.g., deposition, etch, anneal, implant, or other processes. For example, in some embodiments, the surface 204 may be a surface of a structure (e.g., source, drain, gate, fin, or the like), a contact, a liner (e.g., a gettering liner), a barrier layer (e.g., a hydrogen passivation barrier), a metal fill, or the like.

If the substrate 200 is preheated in a separate chamber, the substrate 200 is moved to a treating chamber for treating (e.g., cleaning or roughness reduction as described below). The treating chamber may be any type of chamber suitable to perform the process having a plurality of filaments. For example, in some embodiments, the treating chamber may be a hot wire processing chamber (e.g., a HWCVD chamber or other suitable processing chamber having a hot wire source), for example, such as the process chamber described below. The inventors have observed that by utilizing a chamber having a hot wire source a higher density population of atomic hydrogen (e.g., such as 1.3 to about 3 times higher) may be produced, as compared to methods or systems conventionally used in the semiconductor industry to produce atomic hydrogen (e.g., such as RF and/or DC plasma or inductively coupled plasma systems).

Next, at 103, a surface of an exposed germanium containing material or III-V or II-VI compound containing material (the surface 204) may be treated. In some embodiments, treating the surface 204 may facilitate the removal of contaminants, process residues, or the like (e.g., such as removing the layer 202). Alternatively, or in combination, in some embodiments, treating the surface 204 may reduce a roughness of the surface 204.

To treat the surface 204 of the substrate 200, first, at 104, a hydrogen containing gas may be provided to a process chamber having a plurality of filaments (e.g., a first process chamber). In some embodiments, the process chamber having a plurality of filaments may be the treating chamber described above, or alternatively, a separate chamber. In embodiments where the process chamber is a separate chamber, after decomposing the hydrogen containing gas (described below) the resultant hydrogen atoms may be then provided to the treating chamber.

The hydrogen containing gas may comprise any gas or gases suitable to provide a high density of atomic hydrogen when decomposed. For example, in some embodiments, the hydrogen containing gas may comprise or may consist essentially of or may consist of hydrogen (H₂) gas, a mixture of hydrogen (H₂) gas and nitrogen (N₂) gas, ammonia (NH₃), hydrogen peroxide (H₂O₂), combinations thereof, or the like. In some embodiments, the hydrogen containing gas may further comprise a dilutant gas, for example such as one or more of helium (He), Argon (Ar), or the like. In some embodiments the hydrogen containing gas may consist essentially of or may consist of one or more of hydrogen (H₂) gas, a mixture of hydrogen (H₂) gas and nitrogen (N₂) gas, ammonia (NH₃), hydrogen peroxide (H₂O₂), or combinations thereof, mixed with a dilutant gas such as one or more of helium (He), Argon (Ar), or the like. The hydrogen containing gas may be provided at any flow rate suitable to provide a needed amount of atomic hydrogen to clean the surface 204 of the substrate 200 and may be adjusted in accordance with the substrate 200 and/or process chamber size. For example, in some embodiments where the substrate is a 300 mm diameter semiconductor wafer, the hydrogen containing gas may be provided at a flow rate of up to about 10,000 sccm.

Next, at 106, a current is flowed through the plurality of filaments disposed in the process chamber to raise a temperature of the plurality of filaments to a first temperature sufficient to at least partially decompose the hydrogen containing gas. The current may be flowed through the plurality of filaments prior to, at the same time as, and/or subsequent to preheating the substrate (described above at 102) and/or providing the hydrogen containing gas to the process chamber (described above at 104). In some embodiments, the plurality of filaments may be heated to the first temperature at least prior to providing the hydrogen containing gas. In some embodiments, heating the plurality of filaments to the first temperature may reduce or eliminate contaminants from the plurality of filaments, thereby reducing or eliminating particle formation. In addition, heating the plurality of filaments may eliminate impurities, thereby increasing the stability and/or reliability, and extending the useful life of the plurality of filaments. The plurality of filaments may be any suitable type of filaments disposed in any suitable type of process chamber, for example such as the plurality of filaments disposed in the process chamber described below with respect to FIGS. 3 and 4.

The first temperature may be a temperature suitable to achieve decomposition of the hydrogen containing gas to provide a desired density of atomic hydrogen and to facilitate treating the surface 204, as described below. For example, in some embodiments, the first temperature may be about 10 to about 500 degrees Celsius. Other process-compatible temperatures may be used as appropriate for the substrate and the contaminants to be removed.

Next, at 108, one or more of the surfaces of the exposed germanium containing material or III-V or II-VI compound containing material (e.g., surface 204) on the substrate 200 are cleaned by exposing the substrate 200 to the hydrogen atoms formed from the decomposition of the hydrogen containing gas for a first period of time (e.g., some or all of the materials or contaminants disposed on the substrate are removed). In some embodiments, the highly reactive properties of atomic hydrogen facilitate removal of the layer 202, thereby cleaning the one or more surfaces 216 of the substrate 200, as shown in FIG. 2B. The inventors have also observed that by using atomic hydrogen to remove the layer 202, the layer 202 may be completely removed without leaving any residues, or damaging or oxidizing the surfaces, as compared to a conventional cleaning process such as processes utilizing a plasma and/or a fluorine containing process gas. Completely removing the residues without damaging or oxidizing the surfaces provides a clean, stoichiometric surface suitable for deposition of high quality epitaxial layers and devices deposited via processes such as molecular beam epitaxy (MBE), metal-organic chemical vapor deposition (MOCVD) epitaxy, or the like.

In some embodiments, by exposing the substrate 200 to the hydrogen atoms formed from the decomposition of the hydrogen containing gas, a roughness of the surface 204 may be reduced. Reducing the roughness of the surface 204 may provide an atomically smooth surface and reduce or eliminate the formation of unstable oxides in subsequent deposition or layer forming processes (e.g., the formation of a nitrogen containing layer as described below). In addition, reducing the roughness of the surface 204 of the substrate may improve the electrical properties (e.g., current-voltage (I-V) characteristics, capacitive voltage (C-V) characteristics, or the like) of a finished fabricated device formed atop the substrate 200. In some embodiments, the roughness of the surface may be controlled by varying process parameters, for example, such as the first temperature, pressure, gas flow, filament temperatures, or the like.

The first period of time may be any amount of time needed to facilitate removal of the layer 202 to a satisfactory degree (e.g., completely removed, substantially removed, or the like) and/or to facilitate a desired reduction of roughness of the surface 204 of the substrate 200 and may be varied in accordance to the composition of the layer 202, the substrate 200 size, or the like. For example, in some embodiments, the substrate 200 may be exposed to the atomic hydrogen for a first period of time of about 60 to about 600 seconds. In any of the above embodiments, at least one of the first temperature or period of time may be dependent on the materials used to fabricate the filaments and/or the configuration of the plurality of filaments within the process chamber.

In some embodiments, the substrate 200 is disposed beneath, and directly exposed to, the plurality of filaments in the process chamber. Alternatively, in some embodiments, the substrate 200 may be separated from the plurality of filaments. For example, in some embodiments, a plate having a plurality of apertures (e.g., a gas distribution plate) may be disposed between the plurality of filaments and the substrate 200, for example, as described below with respect the plate 342 in FIGS. 3 and 4. When present, the plate may further allow for independent temperature control of the portion of the chamber having the plurality of filaments disposed therein and the portion of the chamber having the substrate 200 disposed therein, thereby allowing each of the plurality of filaments and the substrate to be maintained at different temperatures, as described below. In another example, in some embodiments the atomic hydrogen may be formed remotely in a process chamber having a plurality of heated filaments or wires (e.g., a hot wire processing chamber) and provided to a separate process chamber (e.g., a treating chamber) having the substrate 200 disposed therein.

The substrate 200 may be positioned under the hot wire source, or under the plate 342, on a substrate support (e.g., substrate support 328 described below with respect to FIG. 3) in a static position or, in some embodiments, movably for dynamic cleaning as the substrate 200 passes under the plate 342.

In addition to the above, additional process parameters may be utilized to facilitate treating the surface 204. For example, the inventors have observed that the density of atomic hydrogen produced may be controlled by the pressure within the process chamber containing the substrate 200 (e.g. the process chamber or separate treating chamber). Accordingly, in some embodiments, the process chamber may be maintained at a pressure of about 1 mTorr to about 10,000 mTorr. In addition, the process chamber may be maintained at any temperature suitable to facilitate treating the surface 204, for example, such as about 10 to about 500 degrees Celsius. The substrate 200 may be maintained at the aforementioned temperature via any suitable heating mechanism or heat source, for example, such as resistive heaters (e.g., a heater embedded within a substrate support) heating lamps, or the like. The inventors have observed that maintaining the process chamber at such temperatures provides additional energy to the process, which may facilitate a more complete decomposition of the hydrogen containing gas to form hydrogen atoms, thereby increasing the throughput and uniformity of the treating process.

After the surfaces of the exposed III-V or II-VI compound containing material (e.g., surface 204) on the substrate 200 are treated at 108, the method 100 generally ends and the substrate 200 may proceed for further processing. In some embodiments, additional processes such as additional layer depositions, etching, annealing, or the like, may be performed on the substrate 200.

Optionally, at 109, after the surfaces of the exposed germanium containing material (e.g., surface 204) on the substrate 200 are treated at 108, a nitrogen containing layer may be formed atop the germanium containing material (e.g., atop the surface 204). To form the nitrogen containing layer, first, at 110, a nitrogen containing gas may be provided to a process chamber having a plurality of filaments (e.g., a second process chamber). In some embodiments, the process chamber having a plurality of filaments may be the treating chamber described above, the first process chamber described above, or a separate chamber. In embodiments where the second process chamber is a separate chamber, after decomposing the nitrogen containing gas (described below) the resultant nitrogen atoms may be then provided to the treating chamber.

The nitrogen containing gas may comprise any gas or gases suitable to provide a high density of atomic nitrogen when decomposed. For example, in some embodiments, the nitrogen containing gas may comprise at least one of nitrogen (N₂), ammonia (NH₃), or the like. In some embodiments, the nitrogen containing gas may further comprise a dilutant gas, for example, such as hydrogen (H₂), helium (He), argon (Ar), or the like. The nitrogen containing gas may be provided at any flow rate suitable to provide a needed amount of atomic nitrogen to form a nitrogen containing layer having a desired thickness and may be adjusted in accordance with the substrate 200 and/or process chamber size. For example, in some embodiments where the substrate is a 300 mm diameter semiconductor wafer, the nitrogen containing gas may be provided at a flow rate of about 1 to about 10,000 sccm and may be varied in accordance with the application, system size, or the like.

Next, at 112, a current is flowed through the plurality of filaments disposed in the process chamber to raise a temperature of the plurality of filaments to a second temperature sufficient to at least partially decompose the nitrogen containing gas. The current may be flowed through the plurality of filaments prior to, at the same time as, and/or subsequent to providing the nitrogen containing gas to the process chamber. In some embodiments, the sequence of flowing the current to the plurality of filaments and providing the nitrogen containing gas may be varied in accordance with a particular application. In some embodiments, the plurality of filaments may be heated to the second temperature at least prior to providing the nitrogen containing gas. The plurality of filaments may be any suitable type of filaments disposed in any suitable type of process chamber, for example such as the plurality of filaments disposed in the process chamber described below with respect to FIGS. 3 and 4.

The second temperature may be any temperature suitable to achieve decomposition of the nitrogen containing gas to provide a desired density of atomic nitrogen and to facilitate forming the nitrogen containing layer, as described below. For example, in some embodiments, the second temperature may be about 1000 to about 2500 degrees Celsius. Other process-compatible temperatures may be used as appropriate for the substrate and the contaminants to be removed.

Next, at 114, a nitrogen containing layer 206 is formed atop the germanium containing material (e.g., the surface 204) by exposing the substrate 200 to the nitrogen atoms formed from the decomposition of the nitrogen containing gas for a second period of time. In some embodiments, exposing the surface 204 to the nitrogen atoms causes a nitridation of the germanium material, thereby forming the nitrogen containing layer 206. The nitrogen containing layer 206 may be any type of layer suitable for a desired application. For example, in some embodiments, the nitrogen containing layer 206 may be a germanium nitride (Ge₃N₄) layer.

The inventors have observed that conventional nitrogen containing layer formation processes in germanium substrate applications typically produce interfacial oxide layers (e.g., a GeO₂ layer formed between the substrate and nitrogen containing layer). Such oxide layers are thermally unstable, water soluble and have poor electrical properties (e.g., current-voltage (I-V) characteristics, capacitive voltage (C-V) characteristics, or the like). However, by exposing the surface 204 to the nitrogen atoms, the inventors have observed that the oxygen containing interfacial layer is reduced or eliminated, thereby producing a nitrogen containing layer 206 that is thermally stable, water insoluble and has improved electrical properties, as compared to conventionally formed nitrogen containing layers atop germanium substrates. In addition, the nitrogen containing layer 206 may be resistant to oxidization and oxygen diffusion, thereby allowing the nitrogen containing layer 206 to be utilized as a passivation layer or a diffusion barrier layer against oxygen for germanium metal insulator semiconductor field effect transistor applications.

The second period of time may be any amount of time needed to form the nitrogen containing layer 206 to a desired thickness and may be varied in accordance to the application, composition of the nitrogen containing layer 206, the substrate 200 size, or the like. For example, in some embodiments, the substrate 200 may be exposed to the atomic nitrogen for a period of time of about 10 to about 600 seconds. In some embodiments, the thickness of the nitrogen containing layer may be detected mechanically (via FTIR, SEM, TEM, XPS, SIMS, etc.) or electrically.

In some embodiments, the substrate 200 is disposed beneath, and directly exposed to, the plurality of filaments in the process chamber. Alternatively, in some embodiments, the substrate 200 may be separated from the plurality of filaments. For example, in some embodiments, a plate having a plurality of apertures (e.g., a gas distribution plate) may be disposed between the plurality of filaments and the substrate 200, for example, as described below with respect the plate 342 in FIGS. 3 and 4. In another example, in some embodiments the atomic nitrogen may be formed remotely in a process chamber having a plurality of heated filaments or wires (e.g., a hot wire processing chamber) and provided to a separate process chamber (e.g., a treating chamber) having the substrate 200 disposed therein.

The substrate 200 may be positioned under the hot wire source, or under the plate 342, on a substrate support (e.g., substrate support 328 described below with respect to FIG. 3) in a static position or, in some embodiments, movably for dynamic deposition as the substrate 200 passes under the plate 342.

In addition to the above, additional process parameters may be utilized to facilitate forming the nitrogen containing layer 206 atop the substrate 200. For example, the inventors have observed that the density of atomic nitrogen produced may be controlled by the pressure within the process chamber containing the substrate 200 (e.g. the process chamber or separate treating chamber). Accordingly, in some embodiments, the process chamber may be maintained at a pressure of less than about 10⁻⁹ mTorr (e.g., an ultra high vacuum) to about 10,000 mTorr. In addition, the substrate 200 may be maintained at any temperature suitable to facilitate forming the nitrogen containing layer 206 atop the substrate 200, for example, such as about 10 to about 500 degrees Celsius. The inventors have observed that maintaining the substrate 200 at such temperatures provides additional energy to the process, which may facilitate a more complete decomposition of the hydrogen containing gas to form hydrogen atoms, thereby increasing the throughput and uniformity of the cleaning process.

The substrate 200 may be maintained at the aforementioned temperature via any suitable heating mechanism or heat source, for example, such as resistive heaters (e.g., a heater embedded within a substrate support) heating lamps, or the like. In addition, the temperature may be monitored via any mechanism suitable to provide an accurate measurement of the temperature. For example, in some embodiments, the temperature may be monitored directly via one or more thermocouples, pyrometers, combinations thereof, or the like. Alternatively, or in combination, in some embodiments, the temperature may be estimated via a known correlation between a power provided to the heating mechanism and the resultant temperature.

Although described as a layer, the nitrogen containing layer 206 may be a partial layer, or may be islands of material formed only upon portions of the substrate 200. For example, in some embodiments, the nitrogen containing layer 206 may be selectively formed atop the substrate 200 to form a portion of a structure 214 (e.g., a source 212, drain 208, or gate 210) atop the substrate 200, such as shown in FIG. 2D.

After forming the nitrogen containing layer 206, the method 100 generally ends and the substrate 200 may proceed for further processing. In some embodiments, additional processes such as additional layer depositions, etching, annealing, or the like, may be performed on the substrate 200.

FIG. 3 depicts a schematic side view of a processing system in accordance with embodiments of the present invention. In some embodiments, the system 300 includes a process chamber 301 (e.g., the first process chamber), a treating chamber 303 and, optionally, a preheat chamber 350. The process chamber 301 may be any type of process chamber having a plurality of filaments disposed therein, for example, such as a hot wire processing chamber (e.g., a HWCVD chamber or other suitable processing chamber having a hot wire source). The process chamber 301 generally comprises a chamber body 302 having an internal processing volume 304 with a hot wire source 348 disposed therein. The hot wire source 348 is configured to provide atomic hydrogen and/or atomic nitrogen to the surface of a substrate 330 (e.g., the device described above) during operation. The hot wire source 348 includes a plurality of filaments or wires 311 coupled to a power source 313 for providing current to heat the plurality of filaments to a temperature sufficient to produce atomic hydrogen or atomic nitrogen from a hydrogen gas or nitrogen gas, respectively, provided for example, from a gas source 346.

The plurality of filaments (wires 311) may be separate wires, or may be a single wire routed back and forth across the internal processing volume 304. The wires 311 may comprise any suitable conductive material, for example, such tungsten, tantalum, iridium, nickel-chrome, palladium, or the like. The wires 311 may comprise any thickness, geometry and/or density suitable to provide a desired density of atomic hydrogen within the process chamber 301. For example, in some embodiments, each wire 311 may have a diameter of about 0.5 mm to about 10 mm. In addition, in some embodiments, the density of each wire may be varied dependent on the application (e.g., substrate composition, material to be removed, or the like). In some embodiments, each wire 311 is clamped in place by support structures to keep the wire taught when heated to high temperature, and to provide electrical contact to the wire. In some embodiments, a distance between each wire 311 (i.e., the wire to wire distance 336) may be varied to provide a desired density of atomic hydrogen within the process chamber 301 in accordance with a particular application. For example, in some embodiments, the wire to wire distance 336 may be about 5 mm to about 80 mm.

The power source 313 is coupled to the wires 311 to provide current to heat the wires 311. The substrate 330 may be positioned under the hot wire source (e.g., the wires 311), for example, on a substrate support 328 disposed within the treating chamber 303. The substrate support 328 may be stationary for static cleaning, or may move (as shown by arrow 354) for dynamic cleaning as the substrate 330 passes under the hot wire source. In some embodiments, a distance between each wire 311 and the substrate 330 (i.e., the wire to substrate distance 340) may be varied to facilitate a particular process (e.g. the inventive method 100 described above) being performed in the process chamber 301. For example, in some embodiments, the wire to substrate distance 340 may be about 10 mm to about 300 mm.

The chamber body 302 further includes one or more gas inlets (one gas inlet 332 shown) coupled to a gas source 346 to provide the cleaning gas and one or more outlets (two outlets 334 shown) to a vacuum pump to maintain a suitable operating pressure within the process chamber 301 and to remove excess process gases and/or process byproducts. The gas inlet 332 may feed into a shower head 333 (as shown), or other suitable gas distribution element, to distribute the gas uniformly, or as desired, over the wires 311.

In some embodiments, the substrate 330 may be separated from the hot wire source (e.g., the wires 311), via a gas distribution apparatus 341, for example, such as a plate 342 having a plurality of through holes 344 configured to distribute the gas (e.g. the atomic hydrogen described above) in a desired manner to the substrate 330. For example, the number of through holes, patterns and dimensions of the plurality of through holes 344 may be varied in accordance with the particular application. For example, in some embodiments, the plurality of through holes 344 may be configured such that the plate 342 may have about 10% to about 50% open area. In some embodiments, each of the plurality of through holes may have a diameter of about 1 mm to about 30 mm.

In some embodiments, when present, the plate 342 may prevent one or more of the wires 311 from contacting the substrate 330 in the event of a mechanical failure of the wires 311. In some embodiments, a distance from the gas distribution apparatus 341 to the substrate 330 may be any distance suitable to provide a desired density of atomic hydrogen to the substrate 330. For example, in some embodiments, the gas distribution apparatus 341 to substrate distance 331 may be about 10 mm to about 200 mm.

The treating chamber 303 generally comprises a chamber body 305 defining an inner volume 307. The substrate support 328 may be positioned within the inner volume 307. In some embodiments, the treating chamber 303 may comprise one or more heaters (not shown) to facilitate heating the substrate. When present, the one or more heaters disposed in the treating chamber 303 may facilitate pre-heating the substrate, for example, such as described above. In some embodiments, one or more shields 320 may be provided to minimize unwanted deposition of materials on interior surfaces of the chamber body 305. The shields 320 and chamber liners 322 generally protect the interior surfaces of the chamber body 305 from undesirably collecting deposited materials due to the cleaning process and/or process gases flowing in the chamber. The shields 320 and chamber liners 322 may be removable, replaceable, and/or cleanable. The shields 320 and chamber liners 322 may be configured to cover every area of the chamber body 305 that could become coated, including but not limited to, around the wires 311 and on all walls of the coating compartment. Typically, the shields 320 and chamber liners 322 may be fabricated from aluminum (Al) and may have a roughened surface to enhance adhesion of deposited materials (to prevent flaking off of deposited material). The shields 320 and chamber liners 322 may be mounted in the desired areas of the process chamber, such as around the hot wire sources, in any suitable manner. In some embodiments, the source, shields, and liners may be removed for maintenance and cleaning by opening an upper portion of the process chamber 301. For example, in some embodiments, the a lid, or ceiling, of the process chamber 301 may be coupled to the chamber body 302 along a flange 338 that supports the lid and provides a surface to secure the lid to the body of the process chamber 301.

In some embodiments, a preheat chamber 350 may be provided to preheat the substrate. The preheat chamber may be any suitable chamber having a heat source 352 for providing heat to the substrate 330 disposed in the preheat chamber 350. The preheat chamber 350 may be coupled directly to the process chamber 301, for example as part of an inline substrate processing tool, or may be coupled to the process chamber 301 via one or more intervening chambers, such as a transfer chamber of a cluster tool. An example of a suitable inline substrate processing tool is described in US Patent Application Publication 2011/0104848A1, by D. Haas, et al., published May 5, 2011, now U.S. Pat. No. 8,117,987, issued Feb. 21, 2012.

A controller 306 may be coupled to various components of the system 300, such as at the process chamber 301, treating chamber 303, or the preheat chamber 350, to control the operation thereof. Although schematically shown coupled to the system 300, the controller may be operably connected to any component that may be controlled by the controller, such as the power source 313, the gas source 346 coupled to the gas inlet 332, a vacuum pump and or throttle valve (not shown) coupled to the outlet 334, the substrate support 328, and the like, in order to control the cleaning process in accordance with the methods disclosed herein. The controller 306 generally comprises a central processing unit (CPU) 308, a memory 312, and support circuits 310 for the CPU 308. The controller 306 may control the system 300 directly, or via other computers or controllers (not shown) associated with particular support system components. The controller 306 may be one of any form of general-purpose computer processor that can be used in an industrial setting for controlling various chambers and sub-processors. The memory, or computer-readable medium, 312 of the CPU 308 may be one or more of readily available memory such as random access memory (RAM), read only memory (ROM), floppy disk, hard disk, flash, or any other form of digital storage, local or remote. The support circuits 310 are coupled to the CPU 308 for supporting the processor in a conventional manner. These circuits include cache, power supplies, clock circuits, input/output circuitry and subsystems, and the like. Inventive methods as described herein may be stored in the memory 312 as software routine 314 that may be executed or invoked to turn the controller into a specific purpose controller to control the operation of the process chamber 301 in the manner described herein. The software routine may also be stored and/or executed by a second CPU (not shown) that is remotely located from the hardware being controlled by the CPU 308.

In some embodiments, the process chamber 301 and the treating chamber 303 may be coupled to one another or constructed integrally with one another to form a unitary process chamber (e.g., such as shown in FIG. 3). Alternatively, in some embodiments, the process chamber 301 and the treating chamber 303 may be separate chambers, such as shown in FIG. 4. In such embodiments, the process gas (e.g., the hydrogen containing gas) may be heated by the wires 311 remotely and the resultant atomic hydrogen may be provided to the treating chamber via, for example, a conduit 402. In some embodiments, the conduit 402 may provide the atomic hydrogen to a cavity or plenum 404 disposed above the gas distribution apparatus 341 and then distributed to the inner volume 307 of the treating chamber 303 via the plurality of through holes 344.

Thus, methods and apparatus for processing germanium containing materials, or III-V or II-VI compound containing materials on substrates are provided herein. Embodiments of the inventive process may advantageously allow for removal of contaminants or undesired layers and a reduction of roughness from a germanium containing material, or III-V or II-VI compound containing materials on a substrate while causing less damage to the substrate as compared to conventional cleaning processes utilizing, for example, one or more of a plasma, a high temperature treatment or a fluorine based chemistry. Moreover, by utilizing a hot wire processing chamber to produce atomic hydrogen, the inventors have observed that a higher density population of atomic hydrogen (e.g., such as 1.3 to about 3 times higher) may advantageously be provided as compared to conventionally used methods to produce atomic hydrogen. Although not limiting of the scope of application of the inventive methods disclosed herein, the inventive methods have been shown to be particularly effective for the cleaning of larger scale substrates for very large scale integration (VLSI) devices, for example, such as 300 mm substrates, about 1000 mm×1250 mm substrates, about 2200 mm×2500 mm substrates, or greater.

While the foregoing is directed to embodiments of the present invention, other and further embodiments of the invention may be devised without departing from the basic scope thereof.

1. A method of processing a material on a substrate, wherein the material is a germanium containing material, a III-V compound containing material, or a II-VI compound containing material, the method comprising:
providing a hydrogen containing gas to a first process chamber having a plurality of filaments;
flowing a current through the plurality of filaments to raise a temperature of the plurality of filaments to a first temperature sufficient to decompose at least a portion of the hydrogen containing gas to form hydrogen atoms; and
treating a surface of an exposed material on a substrate by exposing the material to hydrogen atoms formed by decomposition of the hydrogen containing gas.

2. The method of claim 1, wherein the hydrogen containing gas comprises at least one of hydrogen (H₂), hydrogen (H₂) and nitrogen (N₂), or ammonia (NH₃).

3. The method of claim 1, wherein the surface of the exposed material is treated in the first process chamber.

4. The method of claim 3, further comprising:
preheating the substrate in a preheat chamber different than the first process chamber prior to treating the surface of the exposed material.

5. The method of claim 3, further comprising:
preheating the substrate in the first process chamber prior to treating the surface of the substrate.

6. The method of claim 1, wherein the substrate is disposed in a treating chamber that is different than the first process chamber, and wherein the hydrogen atoms formed by decomposition of the hydrogen containing gas in the first process chamber are provided to the treating chamber to treat the surface of the exposed material.

7. The method of claim 6, further comprising:
preheating the substrate in a preheat chamber different than the treating chamber prior to treating the surface of the exposed material.

8. The method of claim 6, further comprising:
preheating the substrate in the treating chamber prior to treating the surface of the exposed material.

9. The method of claim 1, wherein the process chamber is a hot wire processing chamber.

10. The method of claim 1, wherein treating the surface of the exposed material comprises at least one of removing a layer disposed atop the surface or reducing a roughness of the surface.

11. The method of claim 1, wherein the material is a germanium containing material, the method further comprising:
providing a nitrogen containing gas to a second process chamber having a plurality of filaments;
flowing a current through the plurality of filaments to raise a temperature of the plurality of filaments to a first temperature sufficient to decompose at least a portion of the nitrogen containing gas to form nitrogen atoms; and
forming a nitrogen containing layer atop the germanium containing material by exposing the substrate to nitrogen atoms formed by decomposition of the nitrogen containing gas.

12. The method of claim 11, wherein the nitrogen containing gas comprises at least one of nitrogen (N₂) gas, or ammonia (NH₃).

13. The method of claim 11, wherein the second process chamber is a hot wire processing chamber.

14. The method of claim 11, wherein the substrate is disposed in a deposition chamber that is different than the second process chamber, and wherein the nitrogen atoms formed by decomposition of the nitrogen containing gas in the first process chamber are provided to the deposition chamber to form the nitrogen containing layer atop the substrate.

15. The method of claim 11, wherein the second process chamber is the same as the first process chamber.
